(19) United States
(12) Patent Application Publication
(10) Pub. No.: US 2022/0406510 A1
(43) Pub. Date: Dec. 22, 2022

(54) HEAT EXCHANGER PACKAGE FOR A DRY-TYPE TRANSFORMER

(71) Applicant: Hitachi Energy Switzerland AG, Baden (CH)

(72) Inventors: Qingjun SUN, Shanghai (CN); Qiongfang LU, Shanghai (CN); Ye XU, Shanghai (CN); YuSong YANG, Shanghai (CN)

(73) Assignee: Hitachi Energy Switzerland AG, Baden (CH)

(21) Appl. No.: 17/765,639

(22) PCT Filed: Oct. 18, 2019
(86) PCT No.: PCT/CN2019/111937

§ 371 Date: Mar. 31, 2022

(51) Int. Cl. H01F 27/20; H05K 7/20; H01F 27/02

(52) U.S. Cl. CPC H01F 27/20; H05K 7/20145; H05K 7/20909; H01F 27/025; H05K 7/20172

(57) ABSTRACT

A heat exchanger package for a dry-type transformer is provided. The heat exchanger package includes a package housing including an air inlet and an air outlet and adapted to fix to the dry-type transformer; and a first heat exchanger located in the package housing and between the air inlet and the air outlet, the first heat exchanger arranged at a first angle of inclination with respect to a first inner surface of the package housing.

### CROSS REFERENCE TO RELATED APPLICATIONS

This application is a 35 U.S.C. § 371 national stage application of PCT International Application No. PCT/CN2019/111937 filed on Oct. 18, 2019, the disclosure and content of which is incorporated by reference herein in its entirety.

### TECHNICAL FIELD

Example embodiments of the present disclosure generally relate to a cooling device and more particularly, to a heat exchanger package for a dry-type transformer.

### BACKGROUND

Transformers are widely deployed in various applications to provide various functions, such as voltage conversion. For example, a transformer may be provided in a substation of a power transmission system or a wind mill.

During conversion, some of the input power may not be transformed into desired electrical power. For example, a part of energy may be transformed into heat, causing an increasing temperature of the transformer. The increased temperature may lead to several disadvantages. For example, the transformer may age more rapidly, reducing its service life.

Various approaches have been proposed to reduce temperature of the transformers. For example, a heat exchanger package may be deployed to reduce temperature of the inner space of the dry-type transformer. However, the heat exchanging effect is not satisfactory, and can be further improved.

### SUMMARY

Example embodiments of the present disclosure propose a solution of heat exchanging for a dry-type transformer.

In a first aspect, a heat exchanger package for a dry-type transformer is provided. The heat exchanger package comprises a package housing including an air inlet and an air outlet and adapted to fix to the dry-type transformer; and a first heat exchanger located in the package housing and between the air inlet and the air outlet, the first heat exchanger arranged at a first angle of inclination with respect to a first inner surface of the package housing.

In a second aspect, a dry-type transformer is provided. The dry-type transformer comprises a heat exchanger package of the first aspect; a housing arranged to fix to the heat exchanger package and including an air inlet aligned to the air outlet of the heat exchanger package and an air outlet aligned to the air inlet of the heat exchanger package; and a core component of the dry-type transformer located inside the housing of the dry-type transformer.

In a third aspect, a method for manufacturing a heat exchanger package for a dry-type transformer is provided. The method comprises providing a package housing including an air inlet and an air outlet and adapted to fix to the dry-type transformer; and providing a first heat exchanger located in the package housing and between the air inlet and the air outlet, the first heat exchanger arranged at a first angle of inclination with respect to a first inner surface of the package housing.

According to some embodiments of the present disclosure, the solution according to embodiments of the present disclosure may achieve a better effect of heat exchanging.

### BRIEF DESCRIPTION OF THE DRAWINGS

Through the following detailed descriptions with reference to the accompanying drawings, the above and other objectives, features and advantages of the example embodiments disclosed herein will become more comprehensible. In the drawings, several example embodiments disclosed herein will be illustrated in an example and in a non-limiting manner, wherein:

FIG. 1 illustrates a cross-sectional view of a dry-type transformer mounted with a conventional heat exchanger package;

FIG. 2 illustrates a cross-sectional view of a dry-type transformer mounted with a heat exchanger package in accordance with some example embodiments of the present disclosure;

FIG. 3 illustrates a cross-sectional view of a dry-type transformer mounted with another heat exchanger package in accordance with some example embodiments of the present disclosure;

FIG. 4 illustrates a detailed view of an example of a heat exchanger in accordance with some example embodiments of the present disclosure; and

FIG. 5 illustrates a method of manufacturing a heat exchanger package in accordance with some example embodiments of the present disclosure.

Throughout the drawings, the same or corresponding reference symbols refer to the same or corresponding parts.

### DETAILED DESCRIPTION

The subject matter described herein will now be discussed with reference to several example embodiments. These embodiments are discussed only for the purpose of enabling those skilled persons in the art to better understand and thus implement the subject matter described herein, rather than suggesting any limitations on the scope of the subject matter.

The term “comprises” or “includes” and its variants are to be read as open terms that mean “includes, but is not limited to.” The term “or” is to be read as “and/or” unless the context clearly indicates otherwise. The term “based on” is to be read as “based at least in part on.” The term “being operable to” is to mean a function, an action, a motion or a state can be achieved by an operation induced by a user or an external mechanism. The term “one embodiment” and “an embodiment” are to be read as “at least one embodiment.” The term “another embodiment” is to be read as “at least one other embodiment.”

Unless specified or limited otherwise, the terms “mounted,” “connected,” “supported,” and “coupled” and variations thereof are used broadly and encompass direct and indirect mountings, connections, supports, and couplings. Furthermore, “connected” and “coupled” are not restricted to physical or mechanical connections or couplings. In the description below, like reference numerals and labels are used to describe the same, similar or corresponding parts in the Figures. Other definitions, explicit and implicit, may be included below.

As provided above, the conventional heat exchanger package may be deployed to reduce temperature of the inner space of the dry-type transformer. However, the heat exchanging effect of the conventional heat exchanger package may be unsatisfactory, and can be further improved.

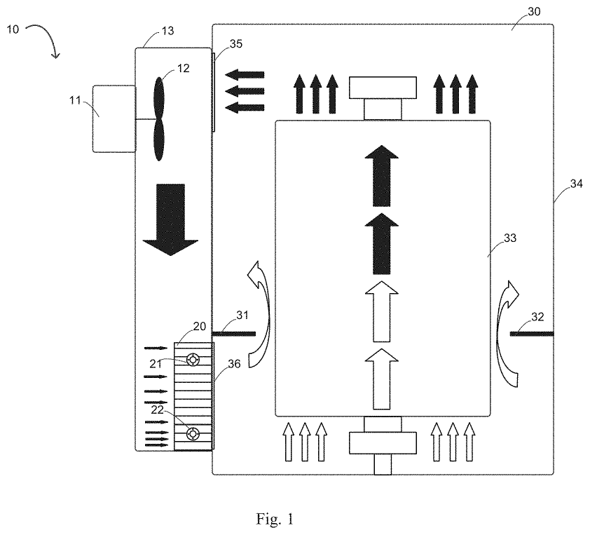

FIG. 1 illustrates a cross-sectional view of a dry-type transformer 30 mounted with a conventional heat exchanger package 10. The dry-type transformer 30 may be applied to an offshore wind mill and may include a housing 34 and a core component 33. The core component contained in the housing may include magnetic core and windings. During operation, the core component may generate significant heat to increase the temperature of the transformer. The temperature of air flow circulating through the core component may increase accordingly.

It could be understood that the housing 34 includes an air outlet 35 aligning to the air inlet of the package housing 13, and the housing 34 includes an air inlet 36 aligning to the air outlet of the package housing 13.

The conventional heat exchanger package 10 is arranged to be mounted or fixed to a back surface of the transformer 30. A conventional heat exchanger package 10 may include a package housing 13, a motor 11 outside the package housing 13, a fan 12 inside the package housing 13, and a heat exchanger 20 inside the package housing 13.

The motor 11 is arranged to drive the fan 12 to spin such that an air flow can be circulated. In FIG. 1, the air flow is illustrated with arrows, in which the solid arrow indicates an air flow part of relatively high temperature, and the hollow arrow indicates air flow part of relatively low temperature. This illustration for temperature of air flow may apply to subsequent figures.

The hot air flows to the bottom of the conventional heat exchanger package 10, and exchanges heat with the fluid of low temperature flowing in the heat exchanger 20 to become cool air exiting from the heat exchanger 20 to the bottom of the inside of the transformer 30.

Some embodiments provide that there is more air flow proximate to the bottom of the package housing 13, and there is less air flow distal from the bottom of the package housing 13. In FIG. 1, such embodiments are illustrated with denser solid arrows proximate to the bottom of the package housing 13, and sparser solid arrows distal from the bottom of the package housing 13. As such, the upper side of the heat exchanger 20 is not utilized efficiently, and a better exchanging effect cannot be achieved even if the heat exchanger extends vertically in the configuration of FIG. 1.

Moreover, in the configuration of FIG. 1, the air hits the bottom surface first, and then turns around to flow through the heat exchanger 20. This turning-around reduces flow speed, and degrades exchanging effect accordingly.

There is a potential risk for the configuration of FIG. 1. In case of a coolant liquid leakage, the liquid coolant, such as water, will be directly blown into the transformer 30. The liquid coolant may potentially cause a fault of the transformer 30. As such, it is desired to remove the potential risk.

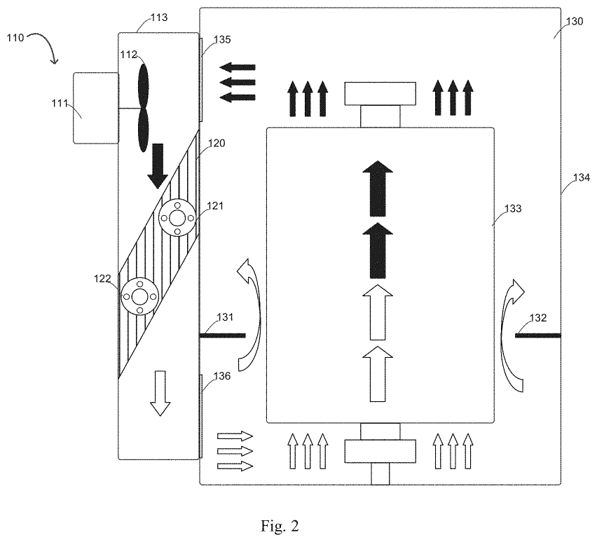

FIG. 2 illustrates a cross-sectional view of a dry-type transformer 130 mounted with a heat exchanger package 110 in accordance with some example embodiments of the present disclosure. The dry-type transformer 130 may be applied to an offshore wind mill and may include a housing 134 and a core component 133.

The core component 133 contained in the housing 134 may include magnetic core and windings. During operation, the core component may generate significant heat to increase the temperature of the transformer. The temperature of air flow circulating through the core component may increase accordingly.

It could be understood that the housing 134 includes an air outlet 135 aligning to the air inlet of the package housing 113, and the housing 134 includes an air inlet 136 aligning to the air outlet of the package housing 113.

The heat exchanger package 110 is arranged to be mounted or fixed to a back surface of the transformer 130. The heat exchanger package 110 includes a package housing 113, a motor 111 outside of the package housing 113, a fan 112 inside of the package housing 113, and a heat exchanger 120 inside the package housing 113.

The motor 111 is arranged to drive the fan 112 to spin, such that an air flow can be circulated. In some embodiments, the fan 112 is arranged to face the air inlet directly, and is arranged to be at a distance from the heat exchanger 120.

In FIG. 2, the air flow is illustrated with arrows, in which the solid arrow indicates an air flow part of relatively high temperature, and the hollow arrow indicates air flow part of relatively low temperature. This illustration for temperature of air flow may apply to subsequent figures.

The hot air flows to the heat exchanger package 110, and exchanges heat with the fluid of low temperature flowing in the heat exchanger 120 to become cool air. The cool air flows to the bottom of the heat exchanger package 110.

The heat exchanger 120 may be an air-forced and/or water-forced heat exchanger, and may include a plurality of fins (not shown) extending in parallel to an air low between the air inlet and the air outlet. The plurality of fins may increase heat dissipation area to obtain a better effect of heat exchange.

As shown in FIG. 2, the heat exchanger 120 is illustrated with a fluid inlet 121 and a fluid outlet 122. The cool fluid flows into the heat exchanger 120 at the fluid inlet 121, and the hot fluid flows out of the heat exchanger 120 at the fluid outlet 122. The fluid may include any coolant in the form of gas, such as air, or liquid, such as water. It could be understood that the positions for fluid inlet and the fluid outlet may be replaced with each other.

The heat exchanger 120 is located in the package housing and between the air inlet and the air outlet, and is arranged at a first angle of inclination with respect to a first inner surface of the package housing 113. It is to be understood that the inclination excludes parallel and perpendicular directions.

As such, even if cooling liquid leakage occurred in the heat exchanger 110, the cooling liquid will not be blown into the transformer 130. For example, a slot or a leakage hole may be arranged at the bottom of the vertical surface to which the motor 111 is mounted. The slot or the leakage hole may be set below the plane at which the lower end of the air outlet of the heat exchanger package is located. This may increase safety of the transformer.

The angle of inclination ranges from 10° to 80°. In some embodiments, the angle of inclination may be 10°, 30°, 45°, 60° or 80°. By setting the heat exchanger 120 inclining to the inner surface and between the air inlet and air outlet, an area of the heat exchanger 110 may be extended, and a thickness of the heat exchanger package 110 may be reduced.

The reduced thickness for the heat exchanger package 110 may be critical for some scenarios, such as offshore wind mills. In these scenarios, there is only limited room for heat exchanger packages, and each inch of thickness counts. With the configuration of FIG. 2, the exchanging effect may be enhanced without increasing size of the heat exchanger packages, and a compact package can be achieved.

Moreover, in the configuration of FIG. 2, the air flow may be guided to flow directly through the heat exchanger 120 without the turning-around as described above. Also, since the air flows in parallel to the fins, the air may be more evenly penetrated through the heat exchanger 120. In this case, the air flow speed is not affected by the turning-around, and a better heat exchanging effect may be achieved.

In some embodiments, the first inner surface is a vertical surface of the package housing 113, and the heat exchanger 120 is arranged to extend from the first inner surface to a second inner surface opposite to the first inner surface, as shown in FIG. 2. Although the heat exchanger 120 is illustrated to contact the opposite vertical surfaces, this is only for illustration without suggesting any limitations as to the scope of the subject matter described here. In some embodiments, the heat exchanger 120 may extend between the opposite vertical surfaces without contacting them.

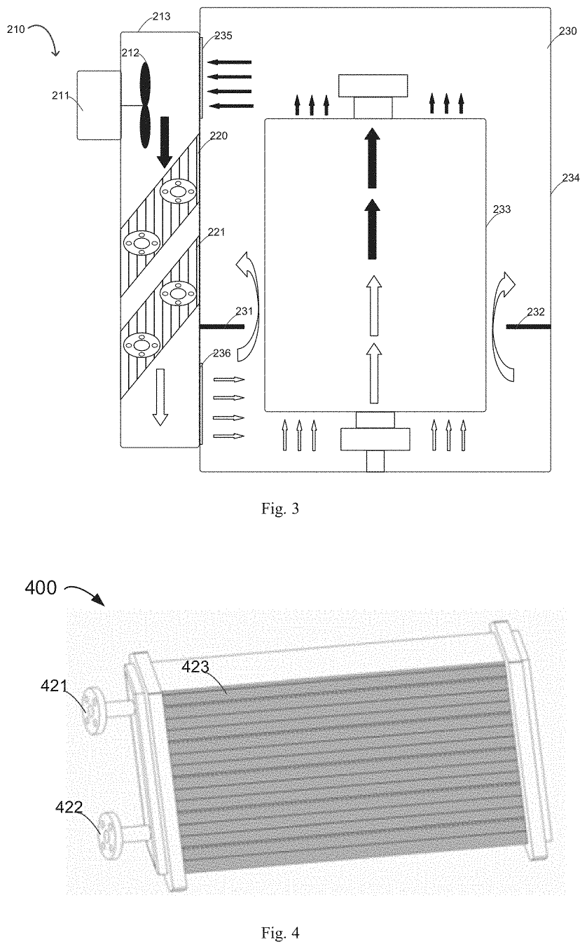

FIG. 3 illustrates a cross-sectional view of a dry-type transformer 230 mounted with another heat exchanger package 210 in accordance with some example embodiments of the present disclosure. The dry-type transformer 230 may be applied to an offshore wind mill, and may include a housing 234 and a core component 233.

The core component 233 contained in the housing 234 may include a magnetic core and windings. During operation, the core component 233 may generate more heat as compared to the core component 133, and the temperature of air flow circulating through the core component may increase accordingly. As such, the temperature of the transformer 230 increases more rapidly, and requires more powerful heat exchanging.

It could be understood that the housing 234 includes an air outlet 235 aligning to the air inlet of the package housing 213, and the housing 234 includes an air inlet 236 aligning to the air outlet of the package housing 213.

The heat exchanger package 210 is arranged to be mounted to or fixed to a back surface of the transformer 230. The heat exchanger package 210 includes a package housing 213, a motor 211 outside of the package housing 213, a fan 212 inside of the package housing 213, and a first heat exchanger 220 inside the package housing 213. The first heat exchanger 220 may be same as or similar to the heat exchanger 120 in some embodiments.

The motor 211 is arranged to drive the fan 212 to spin, such that an air flow can be circulated. In some embodiments, the fan 212 is arranged to face the air inlet directly, and is arranged to be at a distance from the first heat exchanger 220. In FIG. 3, the air flow is illustrated with arrows, in which the solid arrow indicates an air flow part of relatively high temperature, and the hollow arrow indicates air flow part of relatively low temperature.

The hot air flows to the heat exchanger package 210, and exchanges heat with the fluid of low temperature flowing in the first heat exchanger 220 to become cool air. The cool air flows to the bottom of the heat exchanger package 210.

The first heat exchanger 220 may be an air-forced and/or water-forced heat exchanger, and may include a plurality of fins (not shown) extending in parallel to an air flow between the air inlet and the air outlet of the heat exchanger package 210. The plurality of fins may increase heat dissipation area to obtain a better effect of heat exchanging.

The first heat exchanger 220 is located in the package housing and between the air inlet and the air outlet, and is arranged at a first angle of inclination with respect to a first inner surface of the package housing 213. It is to be understood that the inclination excludes parallel and perpendicular directions.

The angle of inclination ranges from 10° to 80°. In some embodiments, the angle of inclination may be 10°, 30°, 45°, 60° or 80°. By setting the first heat exchanger 220 inclining to the inner surface and between the air inlet and air outlet, an area of the heat exchanger 210 may be extended, and a thickness of the heat exchanger package 210 may be reduced.

The reduced thickness for the heat exchanger package 210 may be critical for some scenarios, such as offshore wind mills. In these scenarios, there may only be limited room for heat exchanger packages, and any additional thickness counts. With the configuration of FIG. 3, the exchanging effect may be enhanced without increasing size of the heat exchanger packages.

Moreover, in the configuration of FIG. 3, the air flows directly through the first heat exchanger 220 without the turning-around as described above. Also, since the air flows in parallel to the fins, the air may be more evenly penetrate through the first heat exchanger 220. In this case, the air flow speed is not affected by the turning-around, and a better effect of heat exchanging may be achieved.

In some embodiments, the first inner surface is a vertical surface of the package housing 213, and the first heat exchanger 220 is arranged to extend from the first inner surface to a second inner surface opposite to the first inner surface, as shown in FIG. 3. Although the first heat exchanger 220 is illustrated to contact the opposite vertical surfaces, this is only for illustration without suggesting any limitations as to the scope of the subject matter described here. In some embodiments, the first heat exchanger 220 may extend between the opposite vertical surfaces without contacting them.

In case that more powerful heat exchanging is desired, as described above, the heat exchanger package 210 may further include a second heat exchanger 221 located in the package housing 213 and between the air inlet and the air outlet. The second heat exchanger 221 is arranged at a second angle of inclination with respect to the first inner surface of the package housing, and includes air-forced and/or water-forced heat exchanger.

In some embodiments, the first angle of inclination equals to the second angle of inclination. It can be understood that the first angle of inclination may be different from the second angle of inclination in other examples.

In some embodiments, a size of the second heat exchanger 221 is different from a size of the first heat exchanger 220. For example, since the air flows through the first heat exchanger 220 and then flows through the second heat exchanger 221, less exchanging effect may be required for the second heat exchanger 221. As such, a smaller size may be desired for the second heat exchanger 221. For example, the first heat exchanger 220 may contact the opposite vertical surfaces, and the second heat exchanger 221 may extend between the opposite vertical surfaces without contacting them.

In some embodiments, a shape of the second heat exchanger 221 is different from a shape of the first heat exchanger 220. For example, based on modeling of air flow, different shapes may be utilized for facilitating air circulation to achieve a better effect of heat exchanging.

Although a two-stage configuration of heat exchangers is illustrated in FIG. 3, this is only for illustration without suggesting any limitations as to the scope of the subject matter described here. For some embodiments, the heat exchanger package may include more than two heat exchangers arranged at same or different angles of inclination with respect to a vertical surface of the package housing.

FIG. 4 illustrates a detailed view of an example of a heat exchanger 400 in accordance with some example embodiments of the present disclosure. The heat exchanger 400 may be an example of any of the heat exchangers 120, 220 and 221 in accordance with some example embodiments of the present disclosure.

The heat exchanger 400 includes a fluid inlet 421 and a fluid outlet 422. The cool fluid flows into the heat exchanger at the fluid inlet 421, and the hot fluid flows out of the heat exchanger at the fluid outlet 422 after heat exchanging with the air flow in the heat exchanger package. The fluid may include any coolant in the form of gas, such as air, or liquid, such as water. It could be understood that the positions for fluid inlet and the fluid outlet may be replaced with each other, and shapes and sizes of the fluid inlet and the fluid outlet may vary as needed.

The heat exchanger 400 includes a plurality of fins 423 arranged in parallel to each other. By providing the plurality of fins 423, area of surface of the heat exchanger 400 increases significantly. Thus, area and efficiency for heat exchanging increases accordingly. In an example, the fins 423 extend in parallel to an air low between the air inlet and the air outlet.

For example, the adjacent fins may have a slot or a gap between the adjacent fins to have the air to flow through, and the slot or gap extends in parallel to the air flow. By setting the plurality of fins 423 extending in parallel to an air low, the flow speed may be less affected and the heat exchanging effect can be improved accordingly.

Although a parallel configuration for the plurality of fins 423 is illustrated, this is only for illustration without suggesting any limitations as to the scope of the subject matter described here. It is to be understood that any shape or direction of the plurality of fins 423, as long as they can guide the air flow to the outlet of the heat exchanger package with sufficient heat exchanging.

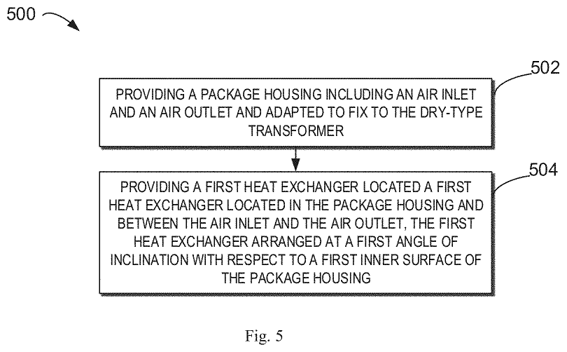

FIG. 5 illustrates a method 500 of manufacturing a heat exchanger package in accordance with some example embodiments of the present disclosure. It could be understood that the features for configurations of FIGS. 2-4 can be applied to the method 500 of FIG. 5.

In 502, it is provided a package housing including an air inlet and an air outlet and adapted to fix to the dry-type transformer. The package housing may include the package housing 113 and the package housing 213 in some embodiments.

In 504, it is provided a first heat exchanger located in the package housing and between the air inlet and the air outlet. The first heat exchanger is arranged at a first angle of inclination with respect to a first inner surface of the package housing. The first heat exchanger may include the heat exchangers 120, 220 and 221 in some embodiments.

Hereinafter, some example implementations of the subject matter described herein will be listed.

Item 1: There is provided a heat exchanger package for a dry-type transformer. The heat exchanger package comprises a package housing including an air inlet and an air outlet and adapted to fix to the dry-type transformer; and a first heat exchanger located in the package housing and between the air inlet and the air outlet, the first heat exchanger arranged at a first angle of inclination with respect to a first inner surface of the package housing.

Item 2: The heat exchanger package of Item 1, wherein the first heat exchanger is arranged to extend from the first inner surface to a second inner surface opposite to the first inner surface, and the first and second inner surfaces are vertical surfaces.

Item 3: The heat exchanger package of Item 1 or 2, wherein the angle of inclination ranges from 10° to 80°.

Item 4: The heat exchanger package of any of Items 1-3, wherein the first heat exchanger includes a plurality of fins extending in parallel to an air low between the air inlet and the air outlet.

Item 5: The heat exchanger package of any of Items 1-4, further comprising: a motor located outside of the package housing; and a fan located inside of the package housing and arranged to be driven by the motor.

Item 6: The heat exchanger package of any of Items 1-5, wherein the fan is arranged to face the air inlet directly.

Item 7: The heat exchanger package of any of Items 1-6, wherein the fan is further arranged to be at a distance from the first heat exchanger.

Item 8: The heat exchanger package of any of Items 1-7, further comprising a second heat exchanger located in the package housing and between the air inlet and the air outlet, the second heat exchanger arranged at a second angle of inclination with respect to the first inner surface of the package housing.

Item 9: The heat exchanger package of any of Items 1-8, wherein the first angle equals to the second angle.

Item 10: The heat exchanger package of any of Items 1-9, wherein a size of the second heat exchanger is different from a size of the first heat exchanger.

Item 11: The heat exchanger package of any of Items 1-10, wherein a shape of the second heat exchanger is different from a shape of the first heat exchanger.

Item 12: The heat exchanger package of any of Items 1-11, wherein the first heat exchanger includes an air-forced and/or water-forced heat exchanger.

Item 13: There is provided a dry-type transformer. The dry-type transformer comprises a heat exchanger package of any of Items of 1-12; a housing arranged to fix to the heat exchanger package and including an air inlet aligned to the air outlet of the heat exchanger package and an air outlet aligned to the air inlet of the heat exchanger package;

and a core component of the dry-type transformer located inside the housing of the dry-type transformer.

Item 14: The dry-type transformer of Item 13, further comprising: an air guide plate, located around an inner surface of the housing of the dry-type transformer and between the air inlet and the air outlet of the housing of the dry-type transformer.

Item 15: There is provided a method for manufacturing a heat exchanger package for a dry-type transformer. The method comprises providing a package housing including an air inlet and an air outlet and adapted to fix to the dry-type transformer; and providing a first heat exchanger located in the package housing and between the air inlet and the air outlet, the first heat exchanger arranged at a first angle of inclination with respect to a first inner surface of the package housing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. On the other hand, various features that are described in the context of a single embodiment may also be implemented in multiple embodiments separately or in any suitable sub-combination.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A heat exchanger package for a dry-type transformer, comprising:
a package housing including an air inlet and an air outlet and adapted to fix to the dry-type transformer; and
a first heat exchanger located in the package housing and between the air inlet and the air outlet, the first heat exchanger arranged at a first angle of inclination with respect to a first inner surface of the package housing.

2. The heat exchanger package of claim 1, wherein the first heat exchanger is arranged to extend from the first inner surface to a second inner surface opposite to the first inner surface, and the first and second inner surfaces are vertical surfaces.

3. The heat exchanger package of claim 1, wherein the angle of inclination ranges from 10° to 80°.

4. The heat exchanger package of claim 1, wherein the first heat exchanger includes a plurality of fins extending in parallel to an air low between the air inlet and the air outlet.

5. The heat exchanger package of claim 1, further comprising:
a motor located outside of the package housing; and
a fan located inside of the package housing and arranged to be driven by the motor.

6. The heat exchanger package of claim 1, wherein the fan is arranged to face the air inlet directly.

7. The heat exchanger package of claim 6, wherein the fan is further arranged to be at a distance from the first heat exchanger.

8. The heat exchanger package of claim 1, further comprising:
a second heat exchanger located in the package housing and between the air inlet and the air outlet, the second heat exchanger arranged at a second angle of inclination with respect to the first inner surface of the package housing.

9. The heat exchanger package of claim 8, wherein the first angle equals to the second angle.

10. The heat exchanger package of claim 8, wherein a size of the second heat exchanger is different from a size of the first heat exchanger.

11. The heat exchanger package of claim 8, wherein a shape of the second heat exchanger is different from a shape of the first heat exchanger.

12. The heat exchanger package of claim 1, wherein the first heat exchanger includes an air-forced and/or water-forced heat exchanger.

13. A dry-type transformer, comprising:
a heat exchanger package of claim 1;
a housing arranged to fix to the heat exchanger package and including an air inlet aligned to the air outlet of the heat exchanger package and an air outlet aligned to the air inlet of the heat exchanger package; and
a core component of the dry-type transformer located inside the housing of the dry-type transformer.

14. The dry-type transformer of claim 13, further comprising:
an air guide plate, located around an inner surface of the housing of the dry-type transformer and between the air inlet and the air outlet of the housing of the dry-type transformer.

15. A method for manufacturing a heat exchanger package for a dry-type transformer, comprising:
providing a package housing including an air inlet and an air outlet and adapted to fix to the dry-type transformer; and
providing a first heat exchanger located in the package housing and between the air inlet and the air outlet, the first heat exchanger arranged at a first angle of inclination with respect to a first inner surface of the package housing.

16. The method of claim 15, wherein the first heat exchanger is arranged to extend from the first inner surface to a second inner surface opposite to the first inner surface, and the first and second inner surfaces are vertical surfaces.

17. The method of claim 15, wherein the first angle of inclination ranges from 10° to 80°.

18. The method of claim 15, wherein the first heat exchanger includes a plurality of fins extending in parallel to an air low between the air inlet and the air outlet.

19. The method of claim 15, further comprising:
providing a motor located outside of the package housing; and
providing a fan located inside of the package housing and arranged to be driven by the motor.

20. The method of claim 19, wherein the fan is arranged to face the air inlet directly, and wherein the fan is further arranged to be at a distance from the first heat exchanger.
